(19) United States
(12) Patent Application Publication
(10) Pub. No.: US 2025/0293040 A1
(43) Pub. Date: Sep. 18, 2025

(54) SUBSTRATE PROCESSING METHOD AND SUBSTRATE PROCESSING APPARATUS

(71) Applicant: SEMES CO., LTD., Cheonan-si (KR)

(72) Inventors: Tae Shin KIM, Suwon-si (KR); Young Dae CHUNG, Incheon-si (KR); Jong Wan KWON, Seongnam-si (KR); Cheng Yeh HSU, Busan-si (KR)

(73) Assignee: SEMES CO., LTD., Cheonan-si (KR)

(21) Appl. No.: 19/079,015

(22) Filed: Mar. 13, 2025

(30) Foreign Application Priority Data
Mar. 14, 2024 (KR) 10-2024-0035942

(51) Int. Cl. H01L 21/311; H01L 21/268; H01L 23/00

(52) U.S. Cl. CPC H01L 21/31111; H01L 21/268; H01L 23/562

(57) ABSTRACT

The present provides a substrate processing method. The substrate processing method includes: a substrate loading step of loading a substrate having a pattern formed on a frontside and having a thin film formed on a backside into a processing space; and a stress alleviation step of alleviating stress applied to the substrate, wherein the stress alleviation step includes: a treatment liquid supply step of supplying a treatment liquid to the thin film; and a heating step of heating the backside of the substrate by emitting a laser to the backside of the substrate, wherein the heating step includes: a laser modulation step of forming a laser emission pattern based on stress applied to each of unit areas on the substrate by modulating the laser using a digital micro-mirror device (DMD) unit; and a laser emission step of emitting the laser emission pattern modulated by the DMD unit to the backside of the substrate.

### CROSS-REFERENCE TO RELATED APPLICATIONS

This application claims priority to and the benefit of Korean Patent Application No. 10-2024-0035942 filed in the Korean Intellectual Property Office on Mar. 14, 2024, the entire contents of which are incorporated herein by reference.

### TECHNICAL FIELD

The present disclosure relates to a substrate processing method and a substrate processing apparatus and, in more detail, a method and apparatus for processing a substrate by emitting a laser.

### BACKGROUND ART

In order to manufacture a semiconductor device, various processes such as photolithography, etching, ashing, ion implantation, and thin film deposition are performed on a substrate such as a wafer, and one or more layers are formed on the substrate through steps such as film formation using an insulating or conductive material, lithography, etching, stripping, and cleaning.

As a series of processes of depositing and removing a film on a substrate is repeated, stress is applied to the substrate due to factors such as the type and structure of the film or the heat applied to the substrate during the process, so intrinsic warpage is generated. Warpage generating in a substrate may cause overlay errors in processes such as lithography, etching, and deposition that are performed on the substrate, and causes problems of reducing substrate processing efficiency and decreasing the yield of semiconductor devices.

Accordingly, various attempts have been made to reduce warpage of substrates or alleviate stress applied to substrates. However, the technologies of the related art adopt a method of acquiring a vector-type warpage map for the error in x/y directions of substrates and correcting bending in the up/down direction (second order) by an error-sum, so they have limitations in correcting high-order stress applied asymmetrically and unevenly on substrates.

Further, even though warpage is corrected at a substrate scale, there is a problem in that chip-level warpage formed on a substrate, that is, chip-scale stress cannot be corrected or is difficult to correct.

### SUMMARY OF THE INVENTION

An objective of the present disclosure is to provide a substrate processing method and a substrate processing apparatus that can effectively process substrates.

Further, an objective of the present disclosure is to provide a substrate processing method and a substrate processing apparatus that can effectively alleviate stress asymmetrically applied to substrates.

Further, an objective of the present disclosure is to provide a substrate processing method and a substrate processing apparatus that can effectively alleviate stress with a complicated distribution by asymmetrically heating substrates.

Further, an objective of the present disclosure is to provide a substrate processing method and a substrate processing apparatus that can effectively alleviate die-level or chip-level stress on substrates.

An exemplary embodiment of the present invention, a substrate processing method, comprising: a substrate loading step of loading a substrate having a pattern formed on a frontside and having a thin film formed on a backside into a processing space; and a stress alleviation step of alleviating stress applied to the substrate, wherein the stress alleviation step includes: a treatment liquid supply step of supplying a treatment liquid to the thin film; and a heating step of heating the backside of the substrate by emitting a laser to the backside of the substrate, wherein the heating step may include: a laser modulation step of forming a laser emission pattern based on stress applied to each of unit areas on the substrate by modulating the laser using a digital micro-mirror device (DMD) unit; and a laser emission step of emitting the laser emission pattern modulated by the DMD unit to the backside of the substrate.

According to an embodiment of the present disclosure, the DMD unit includes: micromirrors provided to be rotatable; and a board substrate on which the micromirrors are installed.

According to an embodiment of the present disclosure, an additional process step is performed on the frontside of the substrate after the stress alleviation step, and a thin film removal step of removing the thin film on the backside may performed after the additional process step.

According to an embodiment of the present disclosure, the thin film may a nitride film.

According to an embodiment of the present disclosure, the treatment liquid may a phosphoric acid aqueous solution.

According to an embodiment of the present disclosure, the thin film may deposited on the backside of the substrate by a deposition process.

According to an embodiment of the present disclosure, stress that is applied to each of the unit areas may derived by a stress map that maps stress data from shape data of a surface of the substrate, and the DMD unit forms the emission pattern on the basis of the stress map in the laser modulation step.

According to an embodiment of the present disclosure, in the laser modulation step, thickness data of the thin film for applying reverse stress to the stress existing in the unit areas of the substrate may derived on the basis of the stress map, and the emission pattern is formed on the basis of the thickness data of the thin film.

According to an embodiment of the present disclosure, the substrate may loaded into the processing space with the backside facing up in the substrate loading step

An exemplary embodiment of the present invention, a substrate processing apparatus, comprising: a supporting unit on which a substrate having a pattern surface having a pattern formed thereon and a non-pattern surface having a thin film formed thereon is placed; a treatment liquid supply unit supplying a treatment liquid to the thin film; and a laser emission unit emitting a laser to the thin film of the substrate which is supported on the supporting unit and supplied with the treatment liquid, wherein the laser emission unit includes: a laser source generating a laser; and a Digital Micro-mirror Device (DMD) unit modulating the laser generated by the laser source, wherein the DMD unit may include: micromirrors provided to be rotatable; and a board substrate on which the micromirrors are installed.

According to an embodiment of the present disclosure, the apparatus may further include a control unit, wherein the control unit controls the DMD unit to form a laser emission pattern on the basis of stress applied to each of unit areas on the substrate.

According to an embodiment of the present disclosure, stress that is applied to each of the unit areas may derived by a stress map that maps stress data from shape data of a surface of the substrate, and the DMD unit forms the emission pattern on the basis of the stress map.

According to an embodiment of the present disclosure, the laser emission unit further includes an imaging unit adjusting and emitting the laser modulated by the DMD unit to the substrate to correspond to an area to which the laser is emitted, and the imaging unit may include a plurality of lenses adjusting an area and a path of the modulated laser.

An exemplary embodiment of the present invention, a substrate processing method comprising: a substrate loading step of loading a substrate having a pattern formed on a frontside and having a nitride film formed on a backside into a processing space; and a stress alleviation step of alleviating stress applied to the substrate, wherein the stress alleviation step may include: a treatment liquid supply step of supplying a phosphoric acid aqueous solution to the nitride film; and a heating step of heating the nitride film by emitting a laser to the nitride film.

According to an embodiment of the present disclosure, the heating step includes: a laser modulation step of forming a laser emission pattern based on stress applied to each of unit areas on the substrate by modulating the laser using a digital micro-mirror device (DMD) unit; and a laser emission step of emitting the laser emission pattern modulated by the DMD unit to the nitride film, and a thickness of the nitride film may adjusted differently in the unit areas by adjusting the amount of heating by the laser in the stress alleviation step.

According to an embodiment of the present disclosure, thickness data of the nitride film is derived to apply reverse stress to stress existing in each of the unit areas of the substrate, and the laser emission pattern may formed on the basis of the thickness data of the nitride film in the stress alleviation step.

According to an embodiment of the present disclosure, an additional process is performed on the frontside of the substrate after the stress alleviation step, and the substrate processing method further may include a thin film removal step of removing the nitride film after the additional process.

According to an embodiment of the present disclosure, the nitride film may deposited on the backside of the substrate by a deposition process.

According to an embodiment of the present disclosure, the apparatus may further include a stress map that maps stress data from shape data of a surface of the substrate before the stress alleviation step.

According to an embodiment of the present disclosure, the DMD unit includes: micromirrors provided to be rotatable; and a board substrate on which the micromirrors are installed, and in the laser modulation step, a direction in which the micromirrors each reflect the laser is adjusted, and the laser may modulated by selectively switching an On state for reflecting the laser to the substrate and an Off state for dumping the laser.

The objectives of the present disclosure are not limited thereto and other objectives not stated herein may be clearly understood by those skilled in the art from the following description.

According to an embodiment of the present disclosure, it is possible to effectively process a substrate.

Further, according to an embodiment of the present disclosure, it is possible to effectively alleviate stress asymmetrically applied to a substrate.

Further, according to an embodiment of the present disclosure, it is possible to effectively alleviate stress with a complicated distribution by asymmetrically heating a substrate. Further, according to an embodiment of the present disclosure, it is possible to effectively alleviate die-level or chip-level stress on a substrate.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a plan view schematically showing a substrate processing apparatus according to an embodiment of the present disclosure.

FIG. 2 is a view schematically showing an embodiment of the liquid processing chamber of FIG. 1.

FIG. 3 is a view schematically showing the configuration of the laser emission module of FIG. 2.

FIG. 4 is a graph showing distribution of a laser beam that is output from a laser source and FIG. 5 is a graph showing distribution of a laser beam that has passed through a beam shaper.

FIG. 6 is a view schematically showing the appearance of an optical modulator.

FIG. 7 is a view showing that a laser beam is output from an optical modulator.

FIG. 8 is a view showing that a laser beam output from the optical modulator is removed at an optical dumber.

FIG. 9 is a view illustrating the principle that a laser beam is removed at an optical dumper.

FIG. 10 is a view illustrating an emission pattern of a laser beam that is output from the optical modulator.

FIG. 11 is a flowchart of a substrate processing apparatus according to an embodiment of the present disclosure.

FIG. 12 is a view showing the appearance of the liquid processing chamber when the substrate loading step shown in FIG. 11 is performed.

FIG. 13 is a view showing the appearance of the liquid processing chamber when the chemical solution supply step shown in FIG. 11 is performed.

FIG. 14 is a view showing the appearance of the liquid processing chamber when the heating step shown in FIG. 11 is performed.

FIG. 15 is a view illustrating stress that is applied to a substrate without a thin film formed on a backside.

FIG. 16 is a view illustrating stress that is applied to a substrate supported on a supporting unit before the heating step shown in FIG. 11 is performed.

FIG. 17 is a view illustrating stress that is applied to a substrate supported on a supporting unit after the heating step shown in FIG. 11 is performed.

FIG. 18 is a view showing the appearance of the liquid processing chamber when a rinsing liquid supply step according to an embodiment is performed.

FIG. 19 is a view illustrating a substrate after additional processes and a thin film removal step are performed.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

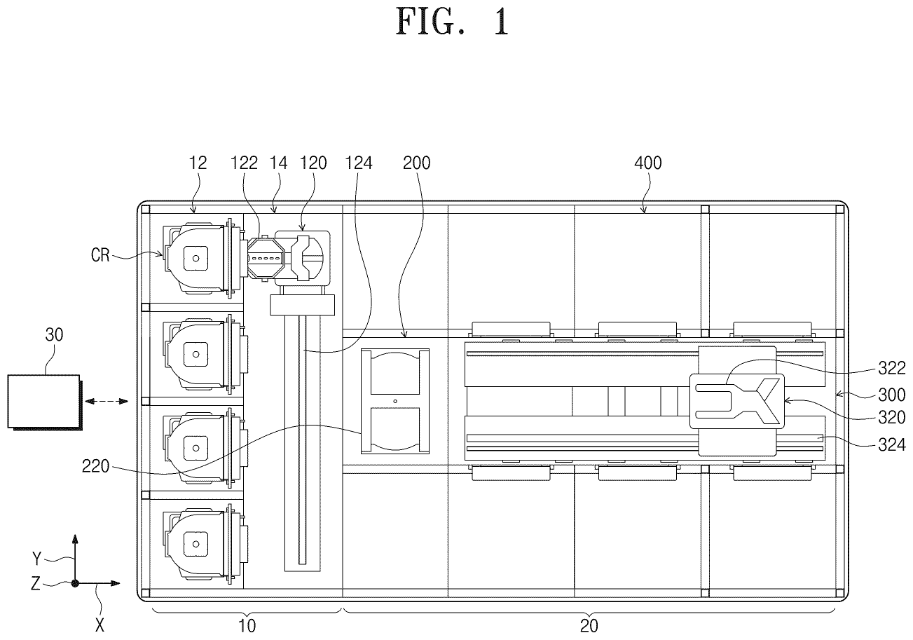

Hereafter, embodiments of the present disclosure are described with reference to FIG. 1 to FIG. 19.

FIG. 1 is a plan view schematically showing a substrate processing apparatus according to an embodiment of the present disclosure.

Referring to FIG. 1, a substrate processing apparatus includes an index module 10, a processing module 20, and a control unit 30. When seen from above, the index module 10 and the processing module 20 are disposed in one direction. Hereafter, the direction in which the index module 10 and the processing module 20 are arranged is referred to as a first direction X, a direction perpendicular to the first direction X when seen from above is referred to as a second direction Y, and a direction perpendicular to both of the first direction X and the second direction Y is referred to as a third direction Z.

The index module 10 transfers substrates W to the processing module 20 from containers CR accommodating the substrates W and loads the substrates W processed at the processing module 20 into the containers CR. The longitudinal direction of the index module 10 is provided in the second direction Y. The index module 10 has a load port 12 and an index frame 14. The load port 12 is positioned at the opposite side of the processing module 20 with the index frame 14 therebetween. A container CR accommodating substrates W is placed in the load port 12. A plurality of load ports 12 may be provided and the plurality of load ports 12 may be disposed in the second direction Y.

The container CR may be a container for sealing such as a Front Open Unified Pod (FOUP). The container CR may be placed in the load port 12 by a worker or a conveying device (not shown) such as an overhead transfer, an overhead conveyor, or an automatic guided vehicle.

An index robot 120 is provided in the index frame 14. A guide rail 124 of which the longitudinal direction is provided in the second direction Y is provided in the index frame 14 and the index robot 120 may be provided to be movable on the guide rail 124. The index robot 120 includes a hand 122 on which substrates W are placed and the hand 122 may be provided to be able to move forward and backward, rotate about the third direction Z, and move in the third direction Z. A plurality of hands 122 is provided to be spaced apart from each other in the up-down direction and the hands 122 can move forward and backward independently from each other.

The control unit 30 can control the components of the substrate processing apparatus. The control unit 30 may include: a process controller that is a microprocessor (computer) that performs control of the operation of the substrate processing apparatus; a user interface that is a keyboard through which an operator performs command input operation, etc. to manage the substrate processing apparatus, a display that visualizes and displays the operation situation of the substrate processing apparatus, etc.; and a memory that stores a control program for performing processing, which is performed in the substrate processing apparatus, under control of the process controller, a program for performing processing on each component in accordance with various data and processing conditions, that is, a processing recipe. Further, the user interface and the memory may be connected to the process controller. The processing recipe may be stored in a memory medium of the memory and the memory medium may be a hard disk and may be a portable disc, such as a CD-ROM and a DVD, or a semiconductor memory such as a flash memory.

The control unit 30 can control the substrate processing apparatus to be able to perform the substrate processing method to be described below. For example, the control unit 30 can control the components provided in a liquid processing chamber 400 to be able to perform the substrate processing method to be described below.

The processing module 20 includes a buffer unit 200, a transfer chamber 300, and a liquid processing chamber 400. The buffer unit 200 provides a space in which substrates W that are loaded into the processing module 20 and substrates W that are unloaded from the processing module 20 temporarily stay. The liquid processing chamber 400 performs a liquid processing process of performing liquid processing on substrates W by supplying a liquid onto the substrates W. The transfer chamber 300 transfers substrates W between the buffer unit 200 and the liquid processing chamber 400.

The longitudinal direction of the transfer chamber 300 may be provided in the first direction X. The buffer unit 200 may be disposed between the index module 10 and the transfer chamber 300. The liquid processing chamber 400 may be disposed at a side of the transfer chamber 300. The liquid processing chamber 400 and the transfer chamber 300 may be disposed in the second direction Y. The buffer unit 200 may be positioned at an end of the transfer chamber 300.

According to an example, liquid processing chambers 400 may be disposed at both sides of the transfer chamber 300. The liquid processing chambers 400 may be provided in an array of A X B (A and B are each a natural number of 1 or more) in the first direction X and the third direction Z, respectively, at a side of the transfer chamber 300.

The transfer chamber 300 has a transfer robot 320. A guide rail 324 of which the longitudinal direction is provided in the first direction X is provided in the transfer chamber 300 and the transfer robot 320 may be provided to be movable on the guide rail 324. The transfer robot 320 includes a hand 322 on which substrates W are placed and the hand 322 may be provided to be able to move forward and backward, rotate about the third direction Z, and move in the third direction Z. A plurality of hands 322 is provided to be spaced apart from each other in the up-down direction and the hands 322 can move forward and backward independently from each other.

The buffer unit 200 has a plurality of buffers 220 on which substrates W are placed. The buffers 220 may be disposed to be spaced apart from each other in the third direction Z. The buffer unit 200 is open on the front face and the rear face. The front face is a surface that faces the index module 10 and the rear face is a surface that faces the transfer chamber 300. The index robot 120 can approach the buffer unit 200 through the front face and the transfer robot 320 can approach the buffer unit 200 through the rear face.

Hereafter, substrates W that are processed in the liquid processing chamber 400 are described in detail.

The processing targets that are processed in the liquid processing chamber 400 may be wafers, glass, photomask, etc. One or more layers may have been formed on substrates W through predetermined processes. A predetermined pattern may have been formed on the frontside or the backside of substrates W. An active region may be included on the frontside or the backside of substrates W. Hereafter, the case in which substrates W that are processed in the liquid processing chamber 400 are wafers with one or more patterns formed on the frontside is exemplified.

Hereafter, a substrate processing apparatus that is provided at the liquid processing chamber 400 is described in detail. The liquid processing chamber 400 performs predetermined processes on substrates M. In more detail, the processes that are performed in the liquid processing chamber 400 may include a process of etching a thin film on a substrate and processes of cleaning, rinsing, and drying the substrate.

A substrate W that is loaded into the liquid processing chamber 400 may require etching of a tin film formed on the frontside or the backside. That is, in the liquid processing chamber 400, one or more thin films formed on substrates W can be etched. Further, the substrates W that are processed in the liquid processing chamber 400 may be post-processed substrates W. In an embodiment, substrates W that are processed in the liquid processing chamber 400 may be substrates on which some or all of a TSV process has been completed on the frontside.

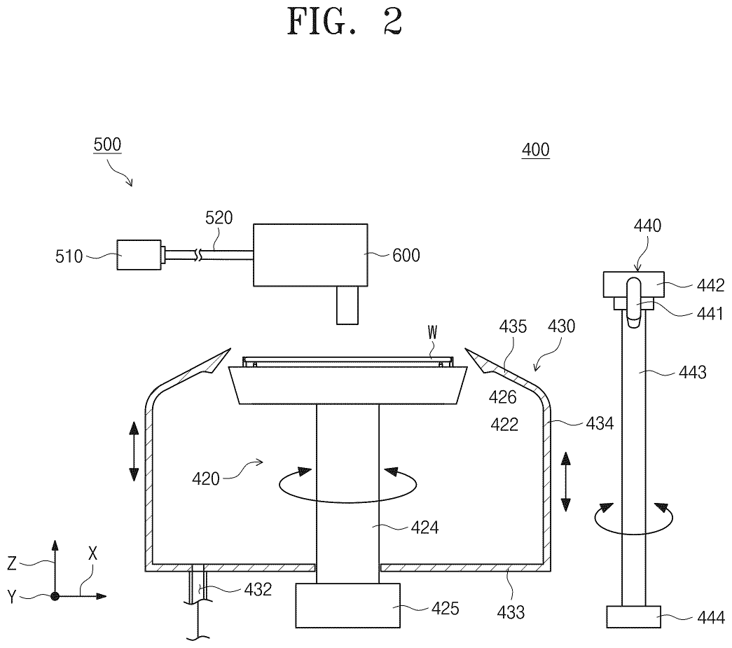

FIG. 2 is a view schematically showing an embodiment of the liquid processing chamber of FIG. 1. Referring to FIG. 2, the liquid processing chamber 400 includes a supporting unit 420, a bowl 430, a chemical solution supply unit 440, and a laser emission assembly 500. Though not shown, the liquid processing chamber 400 may further include a housing surrounding the supporting unit 420, the bowl 430, the chemical solution supply unit 440, and the laser emission assembly 500 and having an in/out port (not shown) through which substrates W can be loaded and unloaded.

The supporting unit 420 can support a substrate W in a processing space 431 defined by the bowl 430 to be described below. The supporting unit 420 can support a substrate W. The supporting unit 420 can rotate a substrate W.

The supporting unit 420 may include a chuck 422, a supporting shaft 424, an actuating member 425, and a supporting pin 426 and a chuck pin 428. The supporting pin 426 and the chuck pin 428 may be installed on the chuck 422. The chuck 422 may have a plate shape having a predetermined thickness. The supporting shaft 424 may be coupled to the lower portion of the chuck 422. The supporting shaft 424 may be a hollow shaft. Further, the supporting shaft 424 can be rotated by the actuating member 425. The actuating member 425 may be a hollow motor. When the actuating member 425 rotates the supporting shaft 424, the chuck 422 coupled to the supporting shaft 424 can be rotated. The substrate W placed on the supporting pin 426 installed on the chuck 233 can also be rotated by rotation of the chuck 422.

The supporting pin 426 can support a substrate W. The supporting pin 426 may have a substantially circular shape when seen from above. Further, when seen from above, the supporting pin 426 may have a shape recessed downward at the portion corresponding to a corner region of a substrate W. That is, the supporting pin 426 may include a first surface supporting the lower portion of a corner region of a substrate W and a second surface facing the side of the corner region of the substrate W to be able to restrict lateral movement of the substrate W when the substrate W is rotated. At least one or more supporting pins 426 may be provided. A plurality of supporting pins 426 may be provided. The supporting pins 426 may be provided in the number corresponding to the number of the corner regions of a substrate W having a rectangular shape. The supporting pins 426 can space the bottom surface of a substrate W and the top surface of the chuck 422 by supporting the substrate W.

A plurality of supporting pins 426 is provided. The supporting pins 426 are disposed with predetermined intervals at the edge portion of the upper surface of the chuck 422 and protrude upward from the chuck 422. The supporting pins 426 are disposed to have entirely a ring shape through a combination thereof. The supporting pins 426 support the edge of the backside of a substrate W such that the substrate W is spaced a predetermined distance apart from the upper surface of the chuck 426.

A plurality of chuck pins 428 is provided. The chuck pins 428 are disposed farther from the center of the chuck 422 than the supporting pins 426. The chuck pins 428 are provided to protrude upward from the chuck 422. When the supporting unit 420 is rotated, the chuck pins 428 support the side of a substrate W to prevent lateral separation of the substrate W from the position. The chuck pins 428 are provided to be movable from a standby position and a supporting position in the radial direction of the chuck 422. The standby position is a position far from the center of the chuck 422 in comparison to the supporting position. When a substrate W is loaded onto or unloaded from the chuck 422, the chuck pins 428 are positioned at the standby positions, and when a process is performed on a substrate W, the chuck pins 346 are positioned at the supporting positions. The chuck pins 428 are in contact with the side of a substrate W at the supporting positions.

The bowl 430 may have a cylindrical shape with an open top. The bowl 430 can define the processing space 431. A substrate W can be liquid-processed and heated in the processing space 431. The bowl 430 can prevent a treatment liquid that is supplied to a substrate W from being scattered and transmitted to the chemical solution supply unit 440 and the laser emission assembly 500.

The bowl 430 may include a bottom portion 433, a vertical potion 434, and an inclined portion 435. An opening in which the supporting shaft 424 can be inserted may be formed through the bottom portion 433 when seen from above. The vertical portion 434 may extend in the third direction Z from the bottom portion 433. The inclined portion 435 may extend at an angle upward from the vertical portion 434. For example, the inclined portion 435 may extend at an angle toward a substrate W supported on the supporting unit 420. A discharge hole 432 that can discharge a treatment liquid, which is supplied from the chemical solution supply unit 440, to the outside may be formed through the bottom portion 433.

Further, the bowl 430 is coupled to an elevation member (not shown), so the position thereof can be changed in the third direction Z. The elevation member may be an actuating device that moves up and down the bowl 430. The elevation member can move up the bowl 430 while liquid processing and/or heating processing is performed on a substrate W, and can move down the bowl 430 when a substrate W is loaded into the liquid processing chamber 400 or a substrate W is unloaded from the liquid processing chamber 400.

The chemical solution supply unit 440 can supply a chemical solution for performing liquid processing on a substrate W. The chemical solution supply unit 440 can supply a chemical solution to a substrate W supported on the supporting unit 420. The chemical solution may be an etching solution or a rinsing liquid. The etching solution may be a chemical. The etching solution may be at least any one selected from a group of a hydrofluoric acid (HF) solution, a sulfuric acid (H₃SO₄) solution, a nitric acid (HNO₃) solution, a phosphoric acid (H₃PO₄) solution, an SC-1 solution (a mixture of ammonium hydroxide (NH₄OH), hydrogen peroxide (H₂O₂), and water (H₂O)), etc. When a thin film f to be described above is silicon nitride (Si₃N₄), the etching solution may, for example, be a phosphoric acid aqueous solution (H₃PO₄+H₂O), but is not limited thereto. The etching solution can etch the thin film formed on a substrate W. The etching solution may be referred to as an etchant. The rinsing liquid can clean a substrate W. A well-known chemical solution may be provided as the rinsing liquid.

The chemical solution supply unit 440 may include a nozzle 441, a fixing body 442, a rotary shaft 443, and a rotary member 444.

The nozzle 411 can supply a treatment liquid to a substrate W supported on the supporting unit 420. A first end of the nozzle 441 may be connected to the fixing body 442 and a second end thereof may extend toward a substrate W from the fixing body 442. The nozzle 411 may extend in the first direction X from the fixing body 442. Further, the second end of the nozzle 411 may extend at an angle toward a substrate W supported on the supporting unit 420.

If necessary, a plurality of nozzles 441 may be provided. Any one of the nozzles 441 may be a nozzle that discharges the etching solution described above and another one of the nozzles 441 may be a nozzle that discharges the rinsing liquid described above.

The body 442 can fix and support the nozzle 441. The body 442 may be connected with the rotary shaft 443 that is rotated around the third direction Z by the rotary member 444. When the rotary member 444 rotates the rotary shaft 443, the body 442 can be rotated around the third direction Z. Accordingly, the outlet of the nozzle 441 can be moved between a liquid supply position that is a position where a treatment liquid is supplied to a substrate W and a standby position that is a position where a treatment liquid is not supplied to a substrate W.

The laser emission assembly 500 can emit a laser to a substrate W. The laser emission assembly 500 can adjust the line width of the pattern formed on a substrate W by emitting a laser to the substrate W with the pattern formed on the top surface by a chemical solution (e.g., an etching solution) that is supplied by the chemical solution supply unit 440. The temperature of the region of a substrate W to which the laser emitted by the laser emission assembly 500 is emitted can be increased. Accordingly, the region emitted with a laser can be relatively more etched and the region not emitted with a laser can be relatively less etched. In this way, it is possible to adjust the line width of the pattern formed on a substrate W.

The laser emission assembly 500 includes a laser source 410, a laser transmission member 520, and a laser emission unit 600.

The laser source 510 can generate light. The laser source 510 can generate light having straightness. The light generated by the laser source 510 can be emitted to a substrate W and can heat the substrate W. The light may be a laser beam, a fiber laser, a laser diode, or the like. Hereafter, it is exemplarily described that light is a laser L. The power of a laser L may be adjusted in accordance with process requirement conditions. The laser source 510 may have power of a range within 20 W per unit area (cm²). When the laser source 510 has power of a range within 20 W per unit area (cm²), an optical modulator 642 to be described below can be appropriately driven without being damaged.

The laser transmission member 520 transmits the laser L generated by the laser source 510 to the laser emission unit 600. According to an example, the laser transmission member 520 may be an optical fiber.

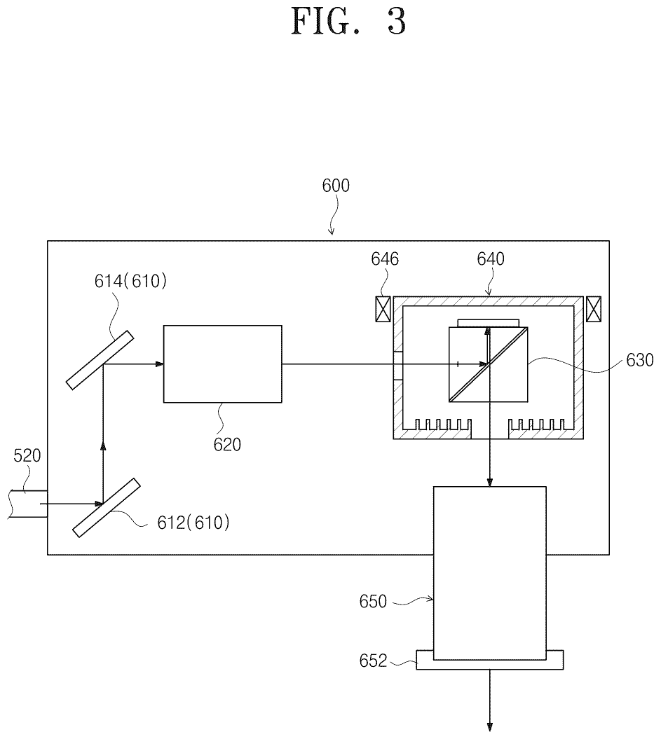

FIG. 3 is a view schematically showing the configuration of the laser emission module of FIG. 2.

The laser emission module 600 includes a mirror 610, a beam shaper 620, a prism optical device 630, an optical modulation unit 640, and an imaging unit 650.

The mirror 610 reflects and transmits a laser L traveling into the laser emission module 600 through the laser transmission member 520 to the beam shaper 620. The mirror 610 may include a plurality of mirrors to appropriately reflect the path of the laser L. For example, the mirror 610 may include a first mirror 612 and a second mirror 614.

The beam shaper 620 can change the type of the light that is output from the laser source 510.

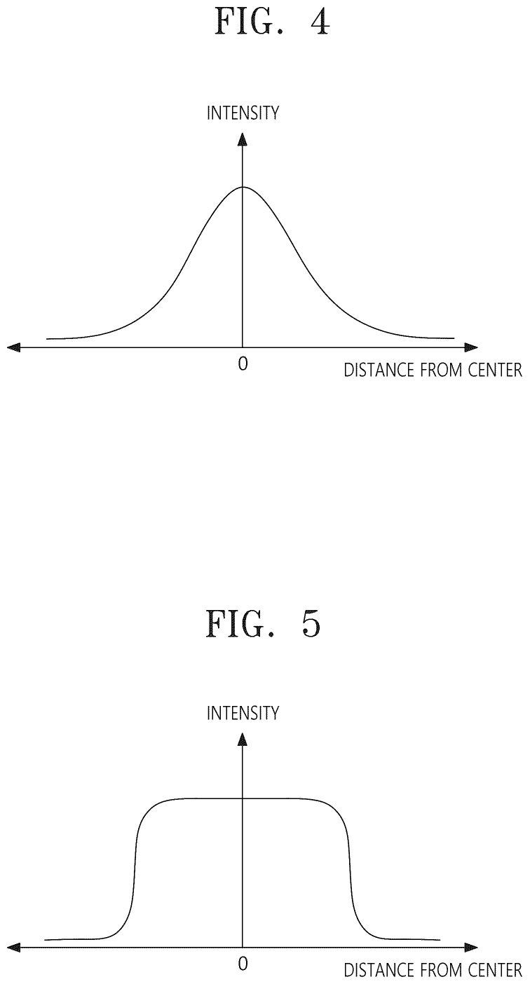

FIG. 4 is a graph showing distribution of a laser beam that is output from a laser source and FIG. 5 is a graph showing distribution of a laser beam that has passed through a beam shaper.

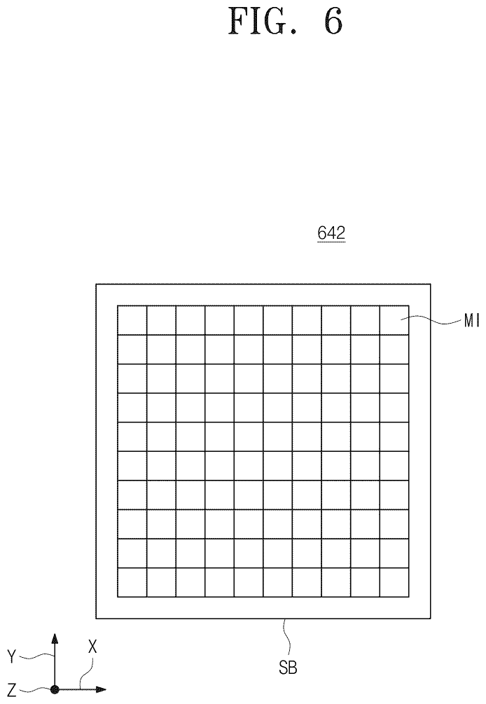

Referring to FIG. 3 to FIG. 5, the laser L that is output from the laser source 510, as shown in FIG. 6, may have a Gaussian type in which the intensity distribution has Gaussian distribution. In more detail, the intensity of the laser L that is output from the laser source 510 may be high at the center of the laser L and the intensity (strength) thereof may gradually decrease as it goes away from the center of the laser L (see FIG. 5). Accordingly, when the laser L that is output from the laser source 510 is emitted to a substrate W, the region close to the center of the laser L can be heated more and the region close to the edge of the laser L can be heated less. Accordingly, in the laser emission module 600 according to an embodiment of the present disclosure, the beam shaper 620 may be disposed on the traveling path of the laser L output from the laser source 510. The beam shaper 620 can change a Gaussian-type laser L that is output from the laser source 510 into a flat top-type laser L. The laser L that is output from the laser source 510 can be converted into a flat top type having flat top distribution, in which the intensity (luminance) distribution is relatively uniform, through the beam shaper 620.

Referring to FIG. 3 again, the laser L that has passed through the beam shaper 620 can be transmitted to the prism optical device 630.

The prism optical device 630 can reflect the laser L that has passed through the beam shaper 620 back to the optical modulation unit 640. The laser L transmitted to the optical modulation unit 640 can be modulated at the optical modulation unit 620 and then output. The laser L modulated and output from the optical modulation unit 640 can be transmitted to the imaging unit 650 through the prism optical device 630.

The optical modulation unit 640 can modulate the transmitted laser L. The optical modulation unit 640 may include an optical modulator 642, an optical dumper 644, and a cooling device 646.

The optical modulator 642 can modulate the shape and the distribution of the laser L that is generated by the laser source 510. In this case, modulation of the shape and the distribution of the laser L may be forming shape and distribution of a laser L corresponding to the emission pattern of a laser L to be emitted to a substrate W.

The optical modulator 642 may be a Digital Micro-mirror Device (DMD).

That is, the optical modulation unit 640 may be a DMD unit including a Digital Micro-mirror Device (DMD).

FIG. 6 is a view schematically showing the appearance of an optical modulator. The optical modulator 642 may include a board substrate SB and a plurality of micromirrors MI. Electrodes corresponding to the plurality of micromirrors MI, respectively, may be installed on the board substrate SB. The control unit 30 can transmit a digital signal of “0” or “1” to the electrodes installed on the board substrate SB. The micromirrors MI may be configured to be rotatable. The micromirrors MI can be configured to be rotatable around a direction that is parallel with a plane passing through the first direction X, the second direction Y, or the first direction X and the second direction Y. A micromirror MI corresponding to an electrode receiving a digital signal of “0” can become an Off state and a micromirror MI corresponding to an electrode receiving a digital signal of “1” can become an On state. A micromirror MI in the On state can emit a laser L to a substrate W and a laser L reflected by a micromirror MI in the Off state may not be emitted to a substrate W.

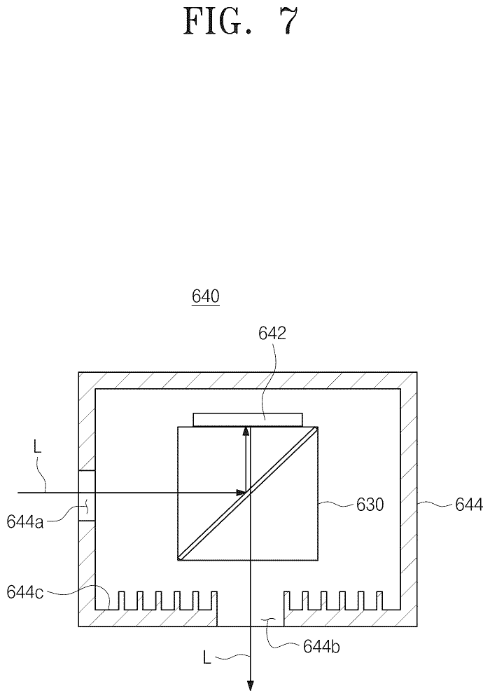

FIG. 7 is a view showing that a laser beam is output from an optical modulator. In FIG. 7, for the convenience of description, the traveling path of light that is reflected by any one micromirror MI of micromirrors MI is shown. Referring to FIG. 3, FIG. 6, and FIG. 7, a micromirror MI in the On state can transmit light to a substrate W through the imaging unit 650 to be described below.

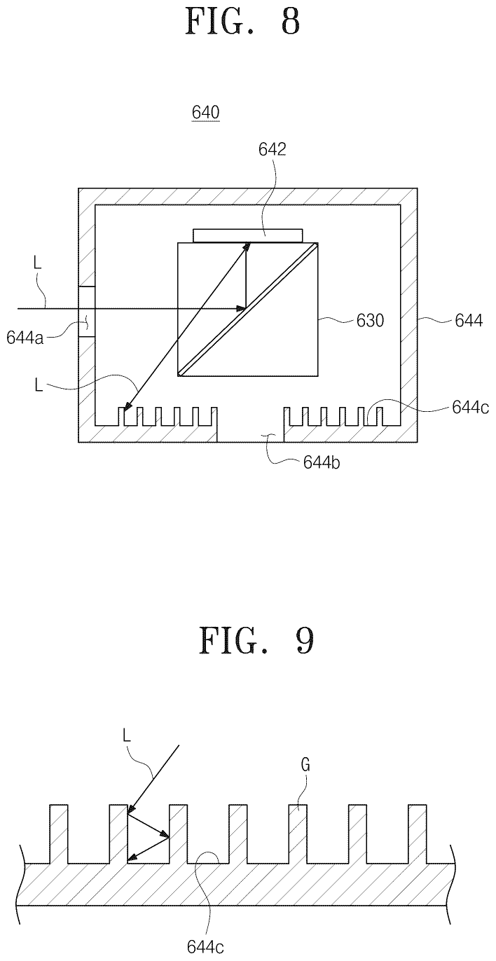

FIG. 8 is a view showing that a laser beam output from the optical modulator is removed at an optical dumber. In FIG. 8, for the convenience of description, the traveling path of a laser L that is reflected by any one micromirror MI of micromirrors MI is shown. Referring to FIG. 3, FIG. 6, and FIG. 8, a micromirror MI in the Off state may not transmit a laser L to a substrate W by reflecting the laser L. In detail, the micromirrors MI are configured to be rotatable, as described above. A micromirror MI in the Off state may make a light not be transmitted to a substrate W by changing the traveling path of a laser L received from the laser source 510 by rotating. The light L that is discharged from the micromirror MI in the Off state may become extinct by being emitted to the inner surface of the optical dumber 644 without passing through a second hole 644b of the optical dumper 644 to be described below. That is, a micromirror in the Off state can dump a laser L.

FIG. 9 is a view illustrating the principle that a laser beam is removed at an optical dumper. Referring to FIG. 3 and FIG. 9, the optical dumber 644 may have a box shape having an internal space. The optical dumber 644 may be made of a material that can remove a laser by absorbing it such as synthetic resin. The prism optical device 630 may be disposed in the internal space of the optical dumber 644. The optical modulator 642 may be disposed in the internal space of the optical dumber 644 or may be installed outside the optical dumber 644.

A first hole 644a and a second hole 644b may be formed at the optical dumber 644. The first hole 644a may be formed on a side of the optical dumber 644. The first hole 644a may be a hole through which the laser L generated by the laser source 510 and converted through the beam shaper 620 passes. The second hole 644b may be a hole through which the laser L modulated by the optical modulator 642 passes. The second hole 644b may be formed on the lower portion of the optical dumber 644.

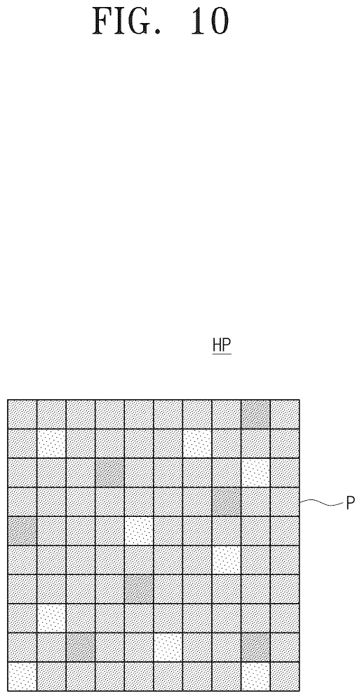

Grooves G may be formed on the inner surface 644c of the optical dumber 644. The grooves G formed on the inner surface 644c of the optical dumber 644 may be configured to be able to absorb the light reflected by a micromirror MI in the Off state. In detail, when a laser L is transmitted to the grooves G, the laser L can be removed by being reflected several times at the grooves G. The laser L can be removed while being reflected several time at the grooves G and losing energy to the optical dumber 644. In FIG. 4 and FIG. 10, it is exemplarily shown that grooves G are formed only on the lower portion of the optical dumber 644, but the present disclosure is not limited thereto and grooves G may be formed on the entire inner surface 644c of the optical dumber 644.

Referring to FIG. 3 again, since the optical dumber 644 removes a laser L, the temperature of the optical dumber 644 can be increased. Accordingly, the optical modulation unit 640 according to an embodiment of the present disclosure may include the cooling device 646 that cools the optical dumber 644. The cooling device 646 may be a fan that generates airflow for cooling the optical dumber 644.

The imaging unit 650 can emit the laser L modulated and output from the optical modulation unit 640 and having passed through the prism optical device 530 to a substrate W by adjusting the laser L to correspond to an area to which the laser L is emitted. The imaging unit 650 includes a plurality of lenses that can adjust the size of a laser L, and can adjust the profile of a laser that is emitted to a substrate W by increasing or decreasing the diameter of laser L.

The imaging unit 650 may include a component that removes a noise pattern from refractive patterns output from the optical modulation unit 640. For example, the imaging unit 650 may include a spatial filter.

The imaging unit 650 includes an emission lens 652. The laser L modulated and output from the optical modulation unit 640 and having passed through the prism optical device 530 is adjusted by the imaging unit 650 and emitted to a substrate W through the emission lens 652.

As described above, the laser L modulated by the optical modulation unit 640 and adjusted by the imaging unit 650 is emitted to a substrate W. The laser emission unit 600 can heat a unit area UA of a substrate W by emitting a laser L to the unit area UA of the substrate W.

The laser emission assembly 500 may further include a moving unit (not shown) that can move between a standby position and a position where a laser L is emitted to a substrate W supported on the supporting unit 420.

FIG. 10 is a view illustrating an emission pattern of a laser beam that is output from the optical modulator. Referring to FIG. 3, FIG. 6, and FIG. 10, as described above, micromirrors MI can be switched between the On state and the Off state. The micromirrors MI each can selectively switch between an On state in which they reflect a laser L to a substrate W and an Off state in which a laser L is dumped, by adjusting the reflective direction of a laser L. The micromirrors MI each can adjust time for which a laser L is emitted to a substrate W by adjusting time for which they maintain the On state and the Off state.

The state change of each micromirror MI between the On state and the Off state can be made within a very short time. By On-Off state change of each micromirror MI, the optical modulation unit 640 can form very various emission patterns HP.

For example, in FIG. 10, the amount of heat that is transmitted to a substrate W per unit time by a laser L reflected by each micromirror MI for unit time (e.g., 1 second) is shown. The emission pattern HP may be composed of a plurality of patterns P corresponding to the micromirrors MI, respectively. In order to increase the amount of heat that is transmitted to a substrate W per unit time from each micromirror MI, it is possible to maintain the On state of the micromirrors MI for a long time and maintain the Off state for a short time. In order to decrease the amount of heat that is transmitted to a substrate W per unit time from each micromirror MI, it is possible to maintain the On state of the micromirrors MI per unit time for a short time and maintain the Off state per unit time for a long time.

Further, the optical modulation unit 640 can change individually or simultaneously the shape or the distribution of a laser L by adjusting the On/Off states of the micromirrors MI described above.

The laser emission unit 600 including the optical modulation unit 640 can determine the emission pattern of a laser L by adjusting the On/Off state of each micromirror MI, can determine the size of an emission region through the imaging unit 650, and then can emit the laser. The unit area UA described above may refer to a region in which a laser L corresponding to one micromirror MI is emitted to a substrate W through the imaging unit 650.

Further, the laser emission module 600 including the optical modulation unit 640 can convert a laser L converted into a flat top type through the beam shaper 620 into a rectangular uniform laser L by adjusting the On/Off state of each micromirror MI and using the imaging unit 650.

Further, the optical modulation unit 640 can change individually or simultaneously the shape or the distribution of a laser L by adjusting the On/Off states of the micromirrors MI described above.

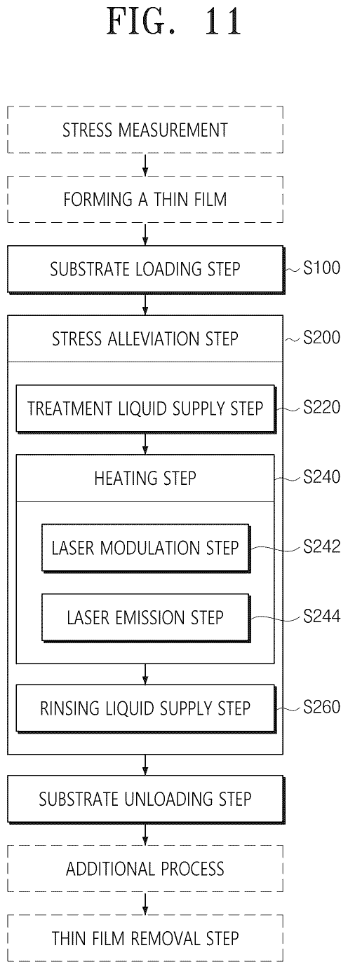

Hereafter, a substrate processing method according to an embodiment of the present disclosure is described with reference to FIG. 11 to FIG. 19. The substrate processing method to be described hereafter is performed by the substrate processing apparatus described above, so the reference numerals cited in FIG. 1 to FIG. 10 are equally cited hereafter.

The substrate processing method to be described below can be performed by the liquid processing chamber 400. Further, the control unit 30 can control the components of the liquid processing chamber 400 so that the liquid processing chamber 400 can perform the substrate processing method to be described below. For example, the control unit 30 can generate a control signal for controlling at least any one of the supporting unit 420, the elevation member 436, the liquid supply unit 440, and the laser emission assembly 500 so that the liquid processing chamber 400 can perform the substrate processing method to be described below.

FIG. 11 is a flowchart of a substrate processing apparatus according to an embodiment of the present disclosure. Referring to FIG. 11, a substrate processing apparatus according to an embodiment of the present disclosure may include a substrate loading step S100 and a stress alleviation step S200. The stress alleviation step S200 may include a chemical solution supply step S220, a heating step S240, and a rinsing liquid supply step S260, and the heating step S240 may include a laser modulation step S242 and a laser emission step S244.

In the substrate loading step S100, a substrate W is loaded into the processing space 431. For example, in the substrate loading step S100, the transfer robot 320 can seat a substrate W on the supporting unit 420. While the transfer robot 320 seats a substrate W on the supporting unit 420, the elevation unit 436 can move down the position of the bowl 430.

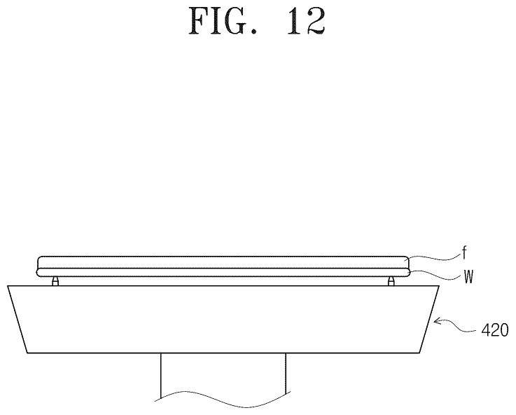

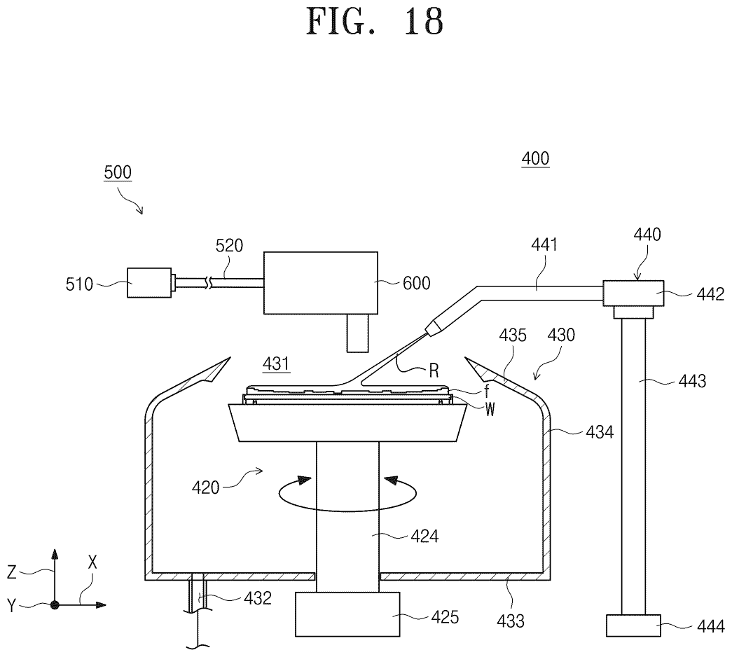

FIG. 12 is a view showing the appearance of the liquid processing chamber when the substrate loading step shown in FIG. 11 is performed. Referring to FIG. 12, a substrate W that is loaded in the substrate loading step S100 may be a substrate W having one or more patterns P1 or one or more layers formed on the frontside and having a thin film f formed on the backside. In more detail, the substrate W may be a substrate W having a thin film f formed on the backside with predetermined stress applied by processing on the frontside. A pattern P1 formed on the frontside of a substrate W is not shown in FIG. 12 to FIG. 14, and FIG. 18.

The thin film f formed on the backside of a substrate W may be a thin film that is etched by an etching solution that is supplied from the chemical solution supply unit 440. For example, the thin film f may be a nitride film. For example, the thin film f may include a silicon nitride (SiN). The thin film may be a thin film of silicon nitride (Si₃N₄). The thin film f may be deposited by a deposition process and then loaded in this state. For example, the thin film f may be deposited on the backside of a substrate W using physical vapor deposition (PVD) or may be deposited on the backside of a substrate W through atomic layer deposition (ALD) or chemical vapor deposition (CVD).

The profile of the surface of a substrate W that is loaded in the substrate loading step S100 can be measured and obtained before the substrate W is loaded into the processing space 431.

The profile of the surface of a substrate W may include stress data for each unit area UA of the substrate. The size of the unit area UA may be the size of the region in which a laser L is emitted to a substrate W through the imaging unit 650 after reflected by one micromirror MI when the substrate W is heated through the optical modulation unit 640.

For example, the profile may include a stress map composed of stress values based on the surface of a substrate W, a strain map composed of strain values based on the surface of the substrate W, or data obtained by mapping information for distortion, that is bending or curving of the shape of the substrate W from shape data of the surface of the substrate W.

In the substrate loading step S100, a substrate W is loaded into the processing space 431 with the backside having the thin film f formed thereon facing up. In other words, the substrate W is laded into the processing space 431 with the frontside having the pattern formed thereon facing down, and the frontside of the substrate W can be supported by the supporting unit 420.

When the substrate loading step S100 is finished, the stress alleviation step S200 is performed. In the stress alleviation step S200, a portion of the thin film f formed on the backside of the substrate W is etched. In more detail, in the stress alleviation step S200, the thin film f formed on the backside of the substrate W is etched to different thicknesses in unit areas UA on the basis of forward stress that is applied to each of the unit areas UA of the substrate W. After the etching process, the thin film f remaining in the unit areas UA applies different reverse stresses to corresponding unit areas UA in accordance with the thicknesses, respectively, whereby it is possible to alleviate the stress that is applied to the substrate W.

As described above, the stress alleviation step S200 may include a chemical solution supply step S220 and a heating step S240. The chemical solution supply step S220 and the heating step S240 may be sequentially performed.

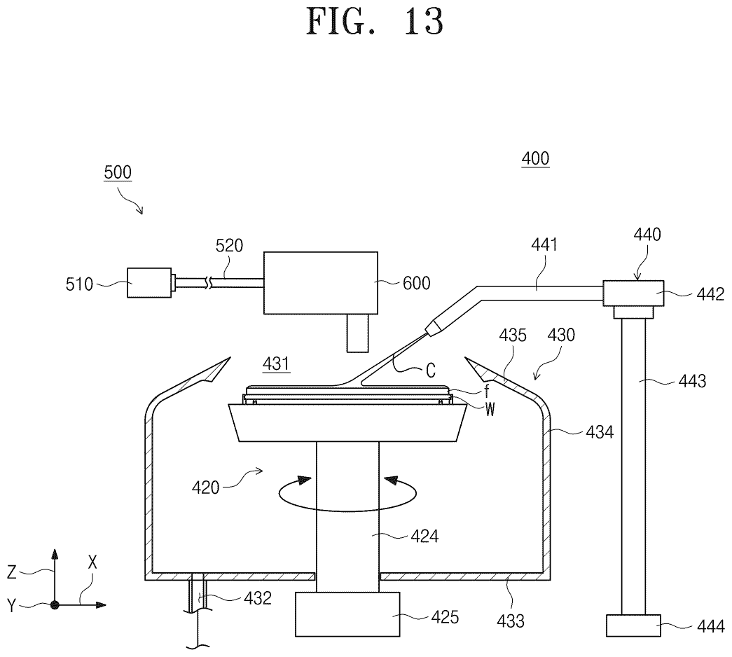

FIG. 13 is a view showing the appearance of the liquid processing chamber when the chemical solution supply step shown in FIG. 11 is performed. As shown in FIG. 13, the chemical solution supply step S220 supplies a chemical solution C onto a substrate W. The chemical solution C that is supplied in the chemical solution supply step S220 may be an etching solution for etching the thin film f. The chemical solution C may be referred to as an etchant. According to an embodiment, in the chemical solution supply step S220, it is possible to supply a chemical solution C to a substrate W that has stopped rotating. When a chemical solution C is supplied to a substrate W that has stopped rotating, the chemical solution C may be supplied by an amount that can form a liquid film or a puddle.

For example, the amount of a chemical solution C that is supplied to a substrate W can be supplied such that it covers the entire top surface of the substrate W and does not flow off the substrate W, or if it flows off, the amount may not be significant. If necessary, it is possible to form a liquid film or a puddle on a substrate W by supplying a chemical solution C to the substrate W that is rotating or by supplying a chemical solution C to the entire top surface of the substrate W while changing the position of the nozzle 452.

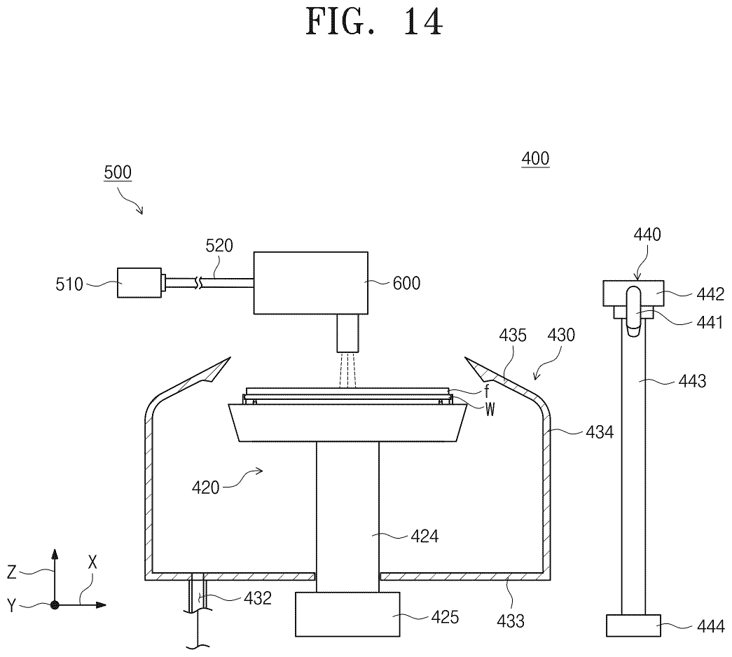

FIG. 14 is a view showing the appearance of the liquid processing chamber when the heating step shown in FIG. 11 is performed. As shown in FIG. 14, in the heating step S240, the substrate W is heated by emitting a laser L to the substrate W. In more detail, the laser emission assembly 500 emits a laser L to a specific region of a substrate W having a liquid film formed thereon. The laser L that is emitted to the substrate W may be emitted to the thin film f formed on the backside of the substrate W.

The laser emission unit 600 can emit a laser to the specific region and then emit a laser to another region that needs to be heated on the substrate W through the moving unit (not shown).

As described above, the heating step S240 may include a laser modulation step S242 and a laser emission step S244.

The laser modulation step S242 and the laser emission step S244 may be sequentially performed.

In the laser modulation step S242, the optical modulation unit 640 can change individually or simultaneously the shape or the distribution of a laser L by adjusting the On/Off states of the micromirrors MI described above and can form an emission pattern of the laser L. The emission pattern of the laser L that is modulated by the optical modulation unit 640 can be derived on the basis of stress data for unit areas of the substrate W obtained before the substrate loading step S100, that is, a stress map of the substrate W.

The control unit 30, on the basis of the stress map of the substrate W, derives a reverse stress map that can alleviate it. The control unit 30 derives a data map of the thickness of the thin film f in each of the unit areas UA such that the unit areas UA of the thin film f formed on the backside of the substrate W can apply stress corresponding to corresponding points, respectively, in accordance with the reverse stress map. The control unit 30 can derive a temperature gradient for heating each unit area UA on the basis of the data map of the thickness of the thin film f in each of the unit areas UA, convert the temperature gradient into an optical profile, and form an emission pattern of a laser L in accordance with the obtained optical profile.

The laser emission step S144 can heat the thin film f by emitting light to the backside of the substrate W having the liquid film formed by the chemical solution C. The entire pattern on the substrate W is etched by the chemical solution C and the region to which the laser L has been emitted can be etched more by heating. The degree of etching depends on the amount of heat transmitted by a laser L per unit time and the optical modulation unit 640 of the present disclosure can form emission patterns having various shapes, so it is possible to control etching for a substrate W in various ways. As described above, since the amount of heating of each of the unit areas UA is adjusted by forming an emission pattern on the basis of the data for the thickness of the thin film f in each of the unit areas UA, it is possible to adjust etching such that the thin film f is etched differently in the unit areas UA. That is, it is possible to adjust the thickness of the thin film f to be different in the unit areas UA by asymmetrically etching the thin film f in the unit areas UA. In the laser emission step S144, the supporting unit 420 can support the substrate W without rotating it.

FIG. 15 is a view illustrating stress that is applied to a substrate without a thin film formed on a backside.

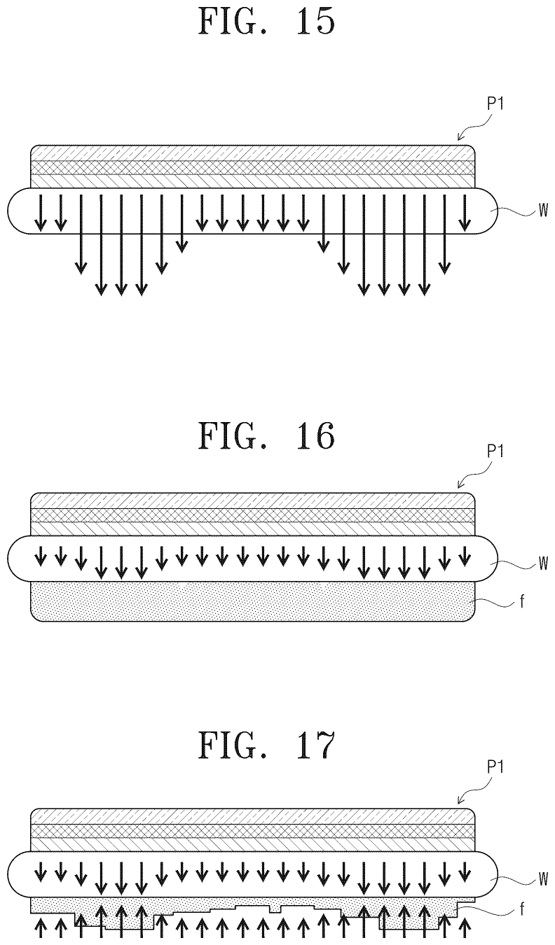

FIG. 16 is a view illustrating stress that is applied to a substrate supported on a supporting unit before the heating step shown in FIG. 11 is performed.

FIG. 17 is a view illustrating stress that is applied to a substrate supported on a supporting unit after the heating step shown in FIG. 11 is performed.

In FIG. 15 to FIG. 17, a substrate W is shown with the frontside thereof having a pattern facing up.

Referring to FIG. 15, as described above, stress is applied to a substrate W having one or more layers, that is, one or more patterns P1 formed on the frontside due to a series of processes of depositing and removing a film. Such stress indicated by arrows in FIG. 15 may cause warpage in a substrate W.

According to an embodiment of the present disclosure, it is possible to form a thin film f on the backside of a substrate W having a pattern P1 on the front side (FIG. 16) and then emit an emission pattern to the thin film f by modulating a laser L such that the thin film f is etched to different thicknesses in the unit areas UA of the substrate W on the basis of the forward stress that is applied to each of the unit areas UA. After the etching process, the thin film f remaining in the unit areas UA applies different reverse stresses to corresponding unit areas UA in accordance with the thicknesses, respectively, whereby, as shown in FIG. 17, it is possible to alleviate the stress that is applied to the substrate W by offsetting the stress. Further, by adjusting the thickness of a thin film f that is formed in a thin film forming step and adjusting the thickness of the thin film f in each of unit areas UA in the stress alleviation step S200, it is possible to adjust the direction and degree of stress that is applied to a substrate W due to the thin film f.

Further, since the etching gradient of a thin film f is adjusted by adjusting the distribution and shape of a laser L differently in unit areas UA using the optical modulation unit 640, it is possible to effectively alleviate not only substrate-scale stress, but more local scale, that is, die-level or chip-level stress on a substrate W, and it is possible to effectively alleviate stress with a complicated distribution expressed in high order by asymmetrically heating a substrate.

After the heating step S240, the rinsing liquid supply step S260 is performed.

FIG. 18 is a view showing the appearance of the liquid processing chamber when a rinsing liquid supply step according to an embodiment is performed. In the rinsing liquid supply step S260, a rinsing liquid R is supplied to the substrate W. In more detail, in the rinsing liquid supply step S260, it is possible to supply a rinsing liquid R to the substrate W that is rotating. The rinsing liquid R supplied to the substrate W can remove etching impurities produced in the process of performing the stress alleviation step S200 from the substrate W. That is, the rinsing liquid R can remove particles of the thin film f etched in the stress alleviation step S200 from the substrate W.

When the rinsing liquid supply step S260 is finished, the substrate can be unloaded from the processing space 431. A drying step may be selectively performed in the liquid processing chamber 400 before the substrate is unloaded. In the drying step, it is possible to dry the substrate W. The drying step may be performed in a drying chamber (not shown) after the substrate is unloaded from the processing space 431.

Additional processes may be performed on the frontside of the substrate W that has undergone the processes including the stress alleviation step S200. For example, processes including one or more of a lithography process and a deposition process may be additionally performed on the frontside of the substrate W. The additional processes that are performed in this case may be applied to the substrate W with an overlay error reduced or minimized due to alleviation of the stress that is applied to the substrate W through the stress alleviation step S200.

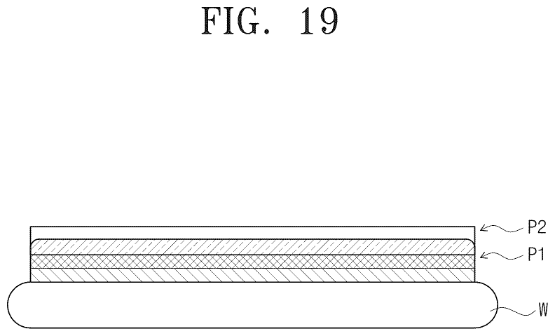

This thin film f on the backside of the substrate W can be removed after the additional processes are finished. FIG. 19 is a view illustrating a substrate after additional processes and a thin film removal step are performed.

Referring to FIG. 19, since additional processes, for example, a deposition process is further performed on the frontside of the substrate W shown in FIG. 17, an additional film P2 is stacked and the thin film f on the backside of the substrate W can be removed.

It was described in the above embodiment and figures that a substrate W having a pattern formed on the frontside and a thin film f on the backside is supported by a supporting unit 420 with the frontside facing down. Additional processing processes may be further performed on the frontside of a substrate W having a pattern on the frontside in order to protect the frontside of the substrate W while a series of processes for etching the backside with the frontside of the substrate W supported on the supporting unit 420. For example, one or more protective layers may be deposited on the frontside of the substrate W before the substrate loading step $100 is performed.

In the above embodiment, it was shown in the figures that, in the heating step S240, as shown in FIG. 14, the laser emission unit 600 emits a laser to a specific region in figures and it was described that it is possible to emit a laser to another region that requires heating on the substrate W through the moving unit (not shown). However, unlike this, the laser emission unit 600 may emit a laser at once to the entire area of the substrate W in the heating step S240.

In the above embodiment, it was described that one laser emission unit 600 emits a laser L to a specific region of a substrate W. However, unlike this, a plurality of laser emission units 600 may be provided and the laser emission units 600 can emit a laser L to different regions of a substrate M, respectively. Alternatively, one laser emission unit 600 may emit a laser L to the entire region of a substrate W.

It was exemplified in the above embodiment that a substrate W that is processed in the liquid processing chamber 400 is a substrate W having one or more patterns P1 or one or more layers formed on the frontside, but the present disclosure is not limited thereto. The substrate processing method according to the present disclosure can also be applied to substrates W with various types and shapes that have stress and require alleviation of the stress such as a mask or a glass substrate.

In the above embodiment, it was described that the size of the unit area UA may be the size of the region in which a laser L is emitted to a substrate W through the imaging unit 650 after reflected by one micromirror MI when the substrate W is heated through the optical modulation unit 640, but the present disclosure is not limited thereto. The size of the unit area UA may be changed in various ways, depending on the size of the substrate W to be processed, the thickness of a thin film to be etched, the required amount of heat, etc., and it is possible to change the sizes of an emission pattern and an emission region by adjusting the micromirrors MI.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

1. A substrate processing method, comprising:
a substrate loading step of loading a substrate having a pattern formed on a frontside and having a thin film formed on a backside into a processing space; and
a stress alleviation step of alleviating stress applied to the substrate,
wherein the stress alleviation step includes:
a treatment liquid supply step of supplying a treatment liquid to the thin film; and
a heating step of heating the backside of the substrate by emitting a laser to the backside of the substrate,
wherein the heating step includes:
a laser modulation step of forming a laser emission pattern based on stress applied to each of unit areas on the substrate by modulating the laser using a digital micro-mirror device (DMD) unit; and
a laser emission step of emitting the laser emission pattern modulated by the DMD unit to the backside of the substrate.

2. The substrate processing method of claim 1, wherein the DMD unit includes:
micromirrors provided to be rotatable; and
a board substrate on which the micromirrors are installed.

3. The substrate processing method of claim 1, wherein an additional process step is performed on the frontside of the substrate after the stress alleviation step, and
a thin film removal step of removing the thin film on the backside is performed after the additional process step.

4. The substrate processing method of claim 1, wherein the thin film is a nitride film.

5. The substrate processing method of claim 1, wherein the treatment liquid is a phosphoric acid aqueous solution.

6. The substrate processing method of claim 1, wherein the thin film is deposited on the backside of the substrate by a deposition process.

7. The substrate processing method of claim 1, wherein stress that is applied to each of the unit areas is derived by a stress map that maps stress data from shape data of a surface of the substrate, and
the DMD unit forms the emission pattern on the basis of the stress map in the laser modulation step.

8. The substrate processing method of claim 7, wherein, in the laser modulation step,
thickness data of the thin film for applying reverse stress to the stress existing in the unit areas of the substrate is derived on the basis of the stress map, and
the emission pattern is formed on the basis of the thickness data of the thin film.

9. The substrate processing method of claim 1, wherein the substrate is loaded into the processing space with the backside facing up in the substrate loading step.

10.-13. (canceled)

14. A substrate processing method comprising:
a substrate loading step of loading a substrate having a pattern formed on a frontside and having a nitride film formed on a backside into a processing space; and
a stress alleviation step of alleviating stress applied to the substrate,
wherein the stress alleviation step includes:
a treatment liquid supply step of supplying a phosphoric acid aqueous solution to the nitride film; and
a heating step of heating the nitride film by emitting a laser to the nitride film.

15. The substrate processing method of claim 14, wherein the heating step includes:
a laser modulation step of forming a laser emission pattern based on stress applied to each of unit areas on the substrate by modulating the laser using a digital micro-mirror device (DMD) unit; and
a laser emission step of emitting the laser emission pattern modulated by the DMD unit to the nitride film, and
a thickness of the nitride film is adjusted differently in the unit areas by adjusting the amount of heating by the laser in the stress alleviation step.

16. The substrate processing method of claim 15, wherein thickness data of the nitride film is derived to apply reverse stress to stress existing in each of the unit areas of the substrate, and
the laser emission pattern is formed on the basis of the thickness data of the nitride film in the stress alleviation step.

17. The substrate processing method of claim 14, wherein an additional process is performed on the frontside of the substrate after the stress alleviation step, and
the substrate processing method further includes a thin film removal step of removing the nitride film after the additional process.

18. The substrate processing method of claim 14, wherein the nitride film is deposited on the backside of the substrate by a deposition process.

19. The substrate processing method of claim 14, further comprising obtaining a stress map that maps stress data from shape data of a surface of the substrate before the stress alleviation step.

20. The substrate processing method of claim 15, wherein the DMD unit includes:
micromirrors provided to be rotatable; and
a board substrate on which the micromirrors are installed, and
in the laser modulation step, a direction in which the micromirrors each reflect the laser is adjusted, and the laser is modulated by selectively switching an On state for reflecting the laser to the substrate and an Off state for dumping the laser.
